(19) United States
(12) Patent Application Publication
(10) Pub. No.: US 2025/0348064 A1
(43) Pub. Date: Nov. 13, 2025

(54) MONITORING SYSTEM FOR DATA CENTER MAINTENANCE

(71) Applicant: Taiwan Semiconductor Manufacturing Company, Ltd., Hsinchu (TW)

(72) Inventors: WENSEN HUNG, ZHUBEI (TW); TSUNG-YU CHEN, HSINCHU (TW)

(21) Appl. No.: 18/659,690

(22) Filed: May 9, 2024

(51) Int. Cl. G05B 23/02

(52) U.S. Cl. CPC G05B 23/0283; G05B 23/027

(57) ABSTRACT

One or more sensors are integrated into a processor module that includes a semiconductor package and a heat sink. A plurality of processor modules is present in a server, and data from each processor module is sent to a digitally integrated monitoring system which can be part of a data center hardware monitoring system. The server may be one of many servers located in a data center. The data may be further sent to a remote data center maintenance center that concurrently monitors several data centers. When compared to different benchmarks, the data can be used to determine in real time whether maintenance is needed for a given processor module.

### BACKGROUND

Various computer applications require the use of a large number of computer processors. Examples of such applications may include high performance computing (HPC), cloud computing, data centers, and artificial intelligence. Maintaining performance across the computer processors is desirable.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of one embodiment of a processor module installed on a motherboard, in accordance with some embodiments of the present disclosure.

FIG. 2 is a bottom view through line A-A in FIG. 1, showing the heat sink having fastener apertures and sensors embedded within the heat sink.

FIG. 3 is a schematic illustration of a set of servers in a data center, and connections to a real-time monitoring system for monitoring the health of the processor modules in the data center.

FIG. 4 is a flow chart illustrating a method for applying a heat sink to a semiconductor package, in accordance with some embodiments.

FIG. 5 is a side cross-sectional view after the semiconductor package is installed upon the motherboard.

FIG. 6 is a side cross-sectional view showing the sensors and heat sink being aligned with the semiconductor package.

FIG. 7 is a flow chart illustrating a method for maintaining a processor module in a server, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure relates to structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example all layers of the structure can be considered to be “on” the substrate, even though they do not all directly contact the substrate. The term “directly” may be used to indicate two layers directly contact each other without any layers in between them. In addition, when referring to performing process steps to the substrate or upon the substrate, this should be construed as performing such steps to whatever layers may be present on the substrate as well, depending on the context.

The present disclosure relates to processor modules with sensors and methods for processing the data received from those sensors to improve device performance and reduce performance variation between those modules. In this regard, semiconductor dies can be packaged in many different ways, such as Package-on-Package (POP) where two semiconductor packages are stacked upon each other, or Chip-on-Wafer-on-Substrate where a semiconductor chip is attached a wafer (e.g. interposer) which is then attached to a substrate (e.g. printed circuit board). These may also be referred to as three-dimensional integrated circuit (3DIC) devices. A thermal interface material (TIM) is applied over the semiconductor die to improve thermal coupling to a heat sink. The heat sink is commonly secured in place relative to the die using a fastener system, for example by using screws at the corners of the heat sink. In some TIM processes, the die is exposed in the package, and the TIM is applied between the die and the heat sink. In other TIM processes, the package includes a lid (which can act as a heat spreader) and the TIM is applied between the lid and the heat sink. TIM pump-out can occur during temperature cycle changes as the package warps, or due to uneven stresses applied to the TIM by differing forces applied by the fastener system across the heat sink. Varying stresses can also cause die crack. This can lead to die shutdown or performance variation. In data centers that contain multiple servers, with each server containing multiple processor modules that include a semiconductor chip or die, high maintenance costs can be incurred.

In the present disclosure, processor modules containing one or more semiconductor dies also include sensors which can provide information on one or more key parameters, in particular pressure sensors and/or temperature sensors. Methods are also provided for monitoring the processor modules present in each server or data center to improve performance and/or reduce maintenance.

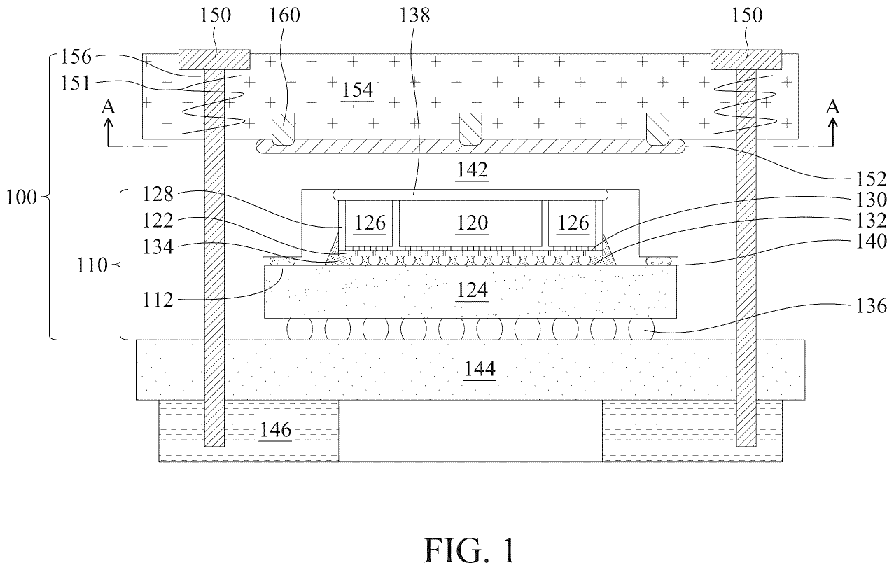

FIG. 1 is a cross-sectional view of one embodiment of a processor module 100 used in the servers and data centers of the present disclosure, which is installed upon a motherboard in a server. Initially, a semiconductor package 110 is shown. Here, the package includes a system-on-a-chip (SoC) 120, a wafer 122, and a substrate 124. On an SoC, many electronic components are combined together on one common substrate. The SoC contains a semiconductor die, and is shown here as being located between two memory chips 126. The SoC 120 generates a relatively large amount of heat compared to the memory chips 126. The SoC may contain, for example, a central processing unit (CPU) or a graphics processing unit (GPU). The memory chips may be, for example, high bandwidth memory (HBM). Other electronic components may also be present. Generally, any number of dies/chips may be present in the package 110 and the processor module 100. The SoC 120 may be surrounded on its sides by an encapsulant 128.

The SoC 120 is bonded to the top surface of a wafer 122. This may be done, for example, through a first interconnect layer 130 containing electrical contacts such as lands, balls, pins, bumps, pillars, or other similar structures. The wafer 122 may be an interposer substrate, formed from a semiconductor substrate like silicon. Sometimes, active devices (like transistors) and passive devices (such as resistors or capacitors) are formed on the surface of the wafer. The wafer may also include through-vias.

The wafer 122 is then bonded to the top surface of a substrate 124 to obtain the semiconductor package 110, which is shown here as a Chip-on-Wafer-on-Substrate. Again, this may be done through a second interconnect layer 132 containing electrical contacts such as lands, balls, pins, bumps, pillars, or other similar structures. The substrate 124 may be, for example, a printed circuit board (PCB), or the like. The substrate 124 may again include other active or passive devices. An underfill material 134 is shown here between the SoC 120 and the wafer 122, and also between the wafer 122 and the substrate 124. The backside of the substrate also includes a third interconnect layer 136 which will be used to join the semiconductor package to the motherboard.

Continuing, a thermal interface material (TIM) is deposited over the semiconductor package 110 to improve thermal coupling. This is referred to herein as an inner TIM layer 138. Suitable TIMs may include polymers, which may contain thermally conductive fillers therein. Some non-limiting examples of thermally conductive fillers may include aluminum oxide, boron nitride, aluminum nitride, aluminum, copper, silver, and indium. The TIM may be a film or a sheet, including for example carbon nanotubes (CNTs) or graphite. The TIM may be in the form of a solid pad, paste, gel, grease, or a phase change material, among others. The TIM may be applied continuously over the package. Sometimes, voids or air gaps may be present within the TIM layer, for example between the SoC 120 and the memory chips 126 to reduce lateral thermal interaction. In some embodiments, the thickness of the TIM layer may range from 100 micrometers (μm) to about 3 millimeters (mm), although other ranges are within the scope of the present disclosure.

An adhesive 140 is also disposed upon the substrate 124 and around the SoC 120. The adhesive 140 may be, for example, an epoxy, or a silicon resin, a glue, or other adhesive suitable for use with semiconductor devices.

A lid 142 is attached to the substrate 124 and over the semiconductor package 110. The lid both physically protects the package 110, and also acts as a heat spreader that dissipates heat generated by the SoC over the greater surface area of the lid. The lid is usually made from a material with high thermal conductivity, such as aluminum, steel, stainless steel, copper, and other similar materials. The lid 142 is affixed to the wafer by the adhesive 140. The adhesive and the TIM may need to be cured by applying heat at a suitable temperature for a suitable time period.

Continuing, then, the semiconductor package 110 will be installed upon a motherboard 144. A backplate 146 may be present underneath the motherboard 144. The backplate provides holes which will engage fasteners 150 to hold the heat sink 154 in place. The backplate can also provide additional support to the motherboard 144. The backplate may be made from, or be coated with, a non-conductive material so as to prevent the creation of short circuits on the backside of the motherboard.

A second TIM layer 152 is placed upon the lid 142, which thermally couples the lid 142 to the heat sink 154. This layer may have the same composition and form as described for the inner TIM layer 138.

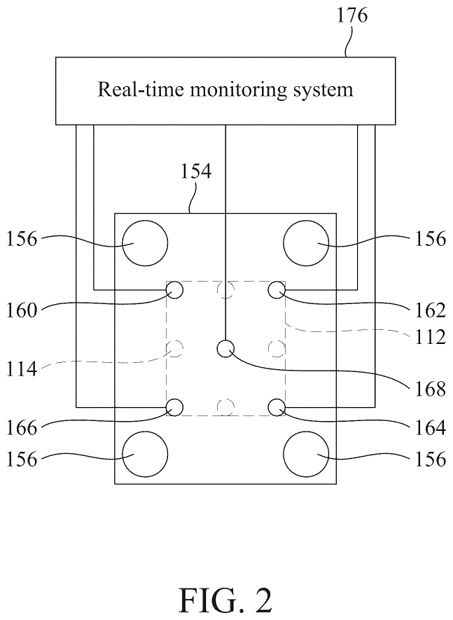

The heat sink 154 is placed above the second TIM layer. The heat sink may be made of materials such as aluminum or copper. The heat sink may include fins to increase surface area. As seen in the bottom plan view of FIG. 2, the heat sink also includes four fastener apertures 156 through which fasteners 150 such as spring-loaded screws will pass (springs 151 are also illustrated). The screws also pass through the motherboard 144 and engage the backplate holes 148. It is noted that multiple semiconductor packages 110 can be installed upon one motherboard. However, each semiconductor package 110 will have its own individual heat sink.

Referring now to both FIG. 1 and FIG. 2, at least one sensor is also located between the package 110 and the heat sink. A plurality of pressure sensors is illustrated here. Five pressure sensors 160, 162, 164, 166, 168 are present, one at each corner of the package along the perimeter, and one sensor 168 in the center of the package. As seen in FIG. 1, the sensors are embedded into the heat sink 154 and the second TIM layer 152. In FIG. 2, the perimeter 112 of the package is indicated with dashed lines. The fastener apertures 156 are outside of the package perimeter, and are located at the corners of the heat sink 154.

In some particular embodiments, the sensors are configured to measure pressure, force, displacement, stress, strain, temperature, or combinations thereof. In some embodiments where the sensor measures pressure/force, the sensor may be a pneumatic pressure sensor, a hydraulic pressure sensor, a strain gauge, or a capacitive pressure sensor. As previously mentioned, uneven pressure distribution can result in pump-out, and uneven heat dissipation during operation, which can affect CPU/GPU performance. A displacement sensor can be used to measure horizontal movement and/or vertical movement, which can correlate with assembly quality. Displacement of as little as 200 to 300 microns could cause contact issues that can result in burnout or other damage to the package. A strain sensor can measure the degree to which the package is bent relative to the substrate (which can be a motherboard), and may be useful for identifying improper assembly or die crack. A temperature sensor can be used to confirm that heat transfer is occurring as expected, and unexpected temperature profiles can indicate issues.

Generally, the sensor(s) can be located in any desired arrangement upon the package. For example, sensors could be located in the center 114 of each side of the package (see FIG. 2). Any combination of sensors may be used for measuring different properties. In some particular embodiments, the at least one sensor comprises at least one pressure sensor and at least one temperature sensor. The sensors permit real-time measurement of key performance indicators (KPI) to ensure uniform pressure, TIM bond line thickness, and a safe stress level upon the package. This aids in maintaining stable package performance from installation to end-of-life.

In other embodiments, the sensor(s) can be embedded into the lid 142. Alternatively, some sensors can be embedded in the heat sink and some sensors can be embedded in the lid.

The combination of the semiconductor package 110 and the heat sink 154 is referred to herein as a processor module 100. It is noted that the present disclosure also extends to bare die packages that do not include a lid and thus only have one TIM layer instead of two TIM layers, and such combinations are also considered processor modules within the scope of the present disclosure.

Although not illustrated, each processor module can also include internal cache, memory, input/output controllers, buses for passing data, and other similar components. Communication channels can include a system bus, network connection, wired, and wireless systems. Each processor module can include one or more cores. Each processor module performs instructions based on software/programming as desired.

Continuing, then, as also illustrated in FIG. 2, each sensor 160 is configured to send data to a monitoring system 176. Put another way, the monitoring system 176 reads or receives signals from each sensor. The monitoring system uses this data to monitor the condition of each processor module.

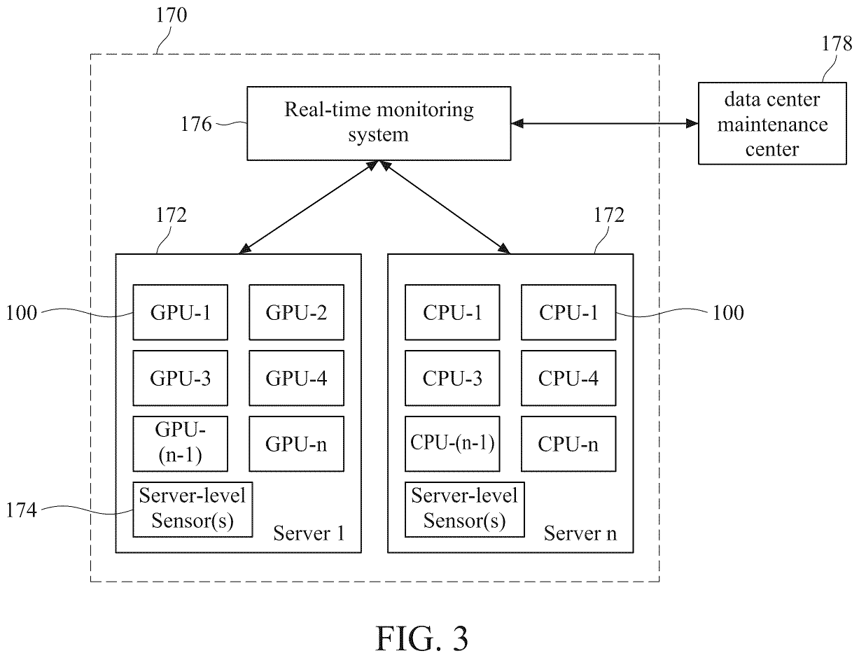

Referring now to FIG. 3, a data center 170 (represented by dashed lines) includes a set of servers 172, labeled here as Server-1 through Server-n. Each server acts as a computing node within the data center. Each server 172 contains multiple processor modules 100, which are labeled here as GPU-1 through GPU-n or CPU-1 through CPU-n for illustrative purposes. This results in a high-performance computing (HPC) environment. Generally, the sensor(s) are located in the same position(s) in each processor module, so that the data gathered from them can be compared to each other in a reliable manner.

Generally, the servers are interconnected by one or more tiers of network switches and routers. Also not illustrated here are power sources, switches, routers, hubs, gateways, firewalls, intrusion detection/prevention devices, computer terminals, printers, memory/storage devices, modems, access points, fire detection and extinguishing systems, wiring, input/output devices, fans, etc. Each server may have server-level sensors 174 which are present in the server and not in a processor module. In particular embodiments, the server-level sensors may include one or more environmental sensors configured to measure temperature, humidity, or moisture. In this regard, comparing server-level temperature to processor module-level temperature may provide information on the efficiency of overall heat transfer or that a piece of server equipment needs maintenance (e.g. a cooling fan). The presence of moisture or humidity can indicate leakage in liquid-based cooling systems, and may also cause electrical problems due to leakage current. Monitoring of these sensors can also improve maintenance of the processor modules within the given server.

Each sensor in the processor modules 100 of the servers sends or transmits data to a real-time monitoring system 176 within the data center 170. This may be done in a wired manner or wirelessly, depending on the setup. The monitoring system receives the data and uses or processes the data to determine whether maintenance is required for any particular processor module or processor modules. The monitoring system may also include a user interface for communicating with operators. The monitoring system may be implemented on one or more general purpose computers, special purpose computer(s), a programmed microprocessor or microcontroller and peripheral integrated circuit elements, an ASIC or other integrated circuit, a digital signal processor, a hardwired electronic or logic circuit such as a discrete element circuit, a programmable logic device such as a PLD, PLA, FPGA, Graphical card CPU (GPU), or PAL, or the like. Such devices typically include at least memory for storing a control program (e.g. RAM, ROM, EPROM) and a processor for implementing the control program.

The data from the sensors may also be sent to a data center maintenance center 178. It is contemplated that the data center maintenance center receives sensor data from multiple data centers. The data center maintenance center may be physically located at a data center or at a separate location. The sensor data can be used for various applications. Such applications may include creating benchmarks and identifying correlations which may improve efficiency, among others.

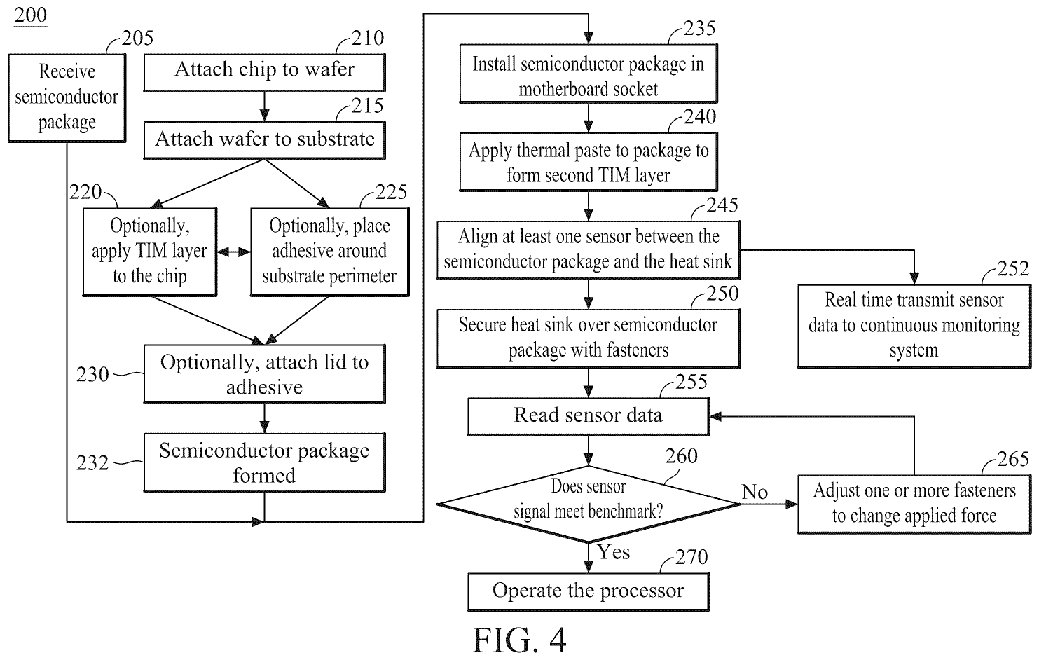

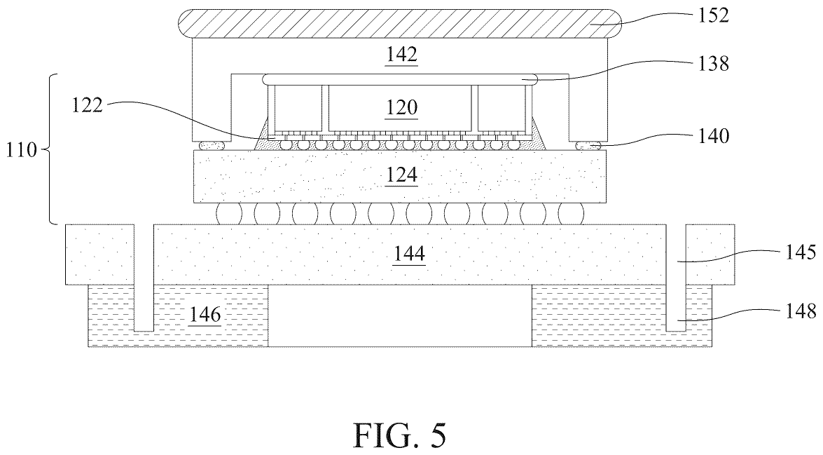

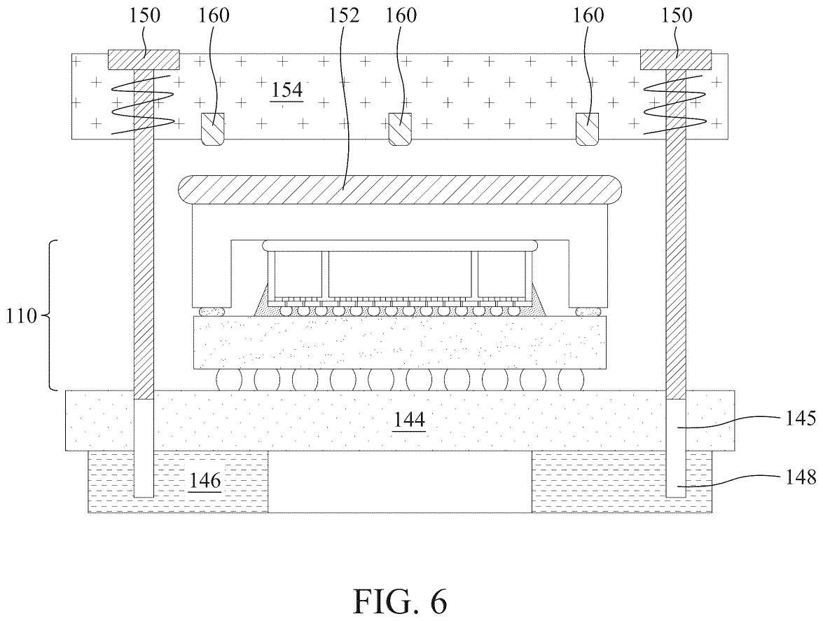

FIG. 4 is a flow chart illustrating a method 200 for applying a heat sink to a semiconductor package, in accordance with some embodiments. Some steps of the method are also illustrated in FIG. 5 and FIG. 6. The method steps are discussed below in terms of forming a single processor module upon a motherboard, and should be construed as also applying to multiple processor modules upon the mother board.

Initially, in step 205 of FIG. 4 and as illustrated in FIG. 5, a semiconductor package 110 is received. The semiconductor package here includes the system-on-chip 120, wafer 122, and substrate 124. Again, a lid 142 is present, but is not required.

Alternatively, a semiconductor package may be formed. In step 210, a chip 120 is attached to a wafer 122. In step 215, the wafer 122 is attached to a substrate 124. These steps would result in a bare die package with TIM applied.

If a lid is desired, then in optional step 220, a thermal interface material (TIM) is applied to the chip to form a first TIM layer 138. In optional step 225, an adhesive 140 is placed around a perimeter of the substrate. The order in which the adhesive and the first TIM layer are formed may be reversed. Then, in optional step 230, a lid 142 is attached to the substrate using the adhesive. The lid also contacts the first TIM layer 138. This results in a semiconductor package 110 as illustrated, which is indicated as step 232.

Continuing, then, in step 235 of FIG. 4, the semiconductor package 110 is installed into a socket of the motherboard 144. In this regard, the motherboard may have one or more sockets. In some embodiments, there may be from 1 to 32 sockets upon the motherboard, although generally other ranges are also within the scope of the present disclosure. Next, in step 240 of FIG. 4, a thermal interface material is applied to the semiconductor package to form a second TIM layer 152. This layer may be formed upon the chip, or upon the lid. The structure after these steps is illustrated in FIG. 5. The motherboard holes 145 and backplate holes 148 are also visible here.

Next, in step 245 of FIG. 4 and as illustrated in FIG. 6, at least one sensor 160 is aligned between the semiconductor package 110 and the heat sink 154. Here in FIG. 6, the sensors 160 are aligned with the heat sink by placing them into holes in the heat sink. The fasteners 150 pass through holes in the heat sink, and are illustrated here as being located partly in the holes 145 in the motherboard 144. This aligns the sensors 160 with the semiconductor package 110. The sensors 160 are thus fixed in place relative to both the semiconductor package 110 and the heat sink 154. It is noted that the sensors 160 do not have to directly contact both the semiconductor package and the heat sink. As best seen in FIG. 1, the sensors directly contact the heat sink 154, and are embedded within the second TIM layer 152. Here, at least one of the sensors is a pressure sensor. Although not illustrated here, the sensors 160 are configured so that their output can be read. In particular embodiments, the sensors are connected to the monitoring system 176, either through physical wiring or wirelessly. This is indicated in step 252, where data is being transmitted in real time to the continuous monitoring system.

Next, in step 250, the heat sink is secured over the semiconductor package using a fastener system. As seen in FIG. 6 and in FIG. 2, four fasteners 150, such as spring-loaded screws, are illustrated at each corner of the heat sink. In step 255, as the fasteners 150 are tightened to hold the heat sink against the second TIM layer, the signal(s) from the pressure sensor(s) are read.

In step 260 of FIG. 4, the signal(s) from the sensor(s) are compared to a benchmark to determine whether setup quality is met. In this regard, each fastener has some tolerance. Normally, when the fastener is being manually tightened, an individual torque or force is being applied to each fastener which may also vary depending on the individual doing the tightening. This can introduce deviations in the force being applied by each fastener to lock the semiconductor package and heat sink on the motherboard. Different forces at each location can cause the package to tilt. One application of the monitoring system is to improve the uniformity of the pressure applied across the semiconductor package 110.

Referring back to FIG. 2, five pressure sensors 160, 162, 164, 166, 168 are shown. During installation, the benchmark may be whether the pressure is at a particular target pressure value. Alternatively, the benchmark could be whether the pressure is within a target pressure range, for example from about 10 psi to about 40 psi. In some embodiments, the benchmark is the same for each sensor, regardless of its location. However, this may depend on the package size and the planarity of the lid. For example, if the lid is curved, the benchmark for the center sensor 168 might be higher than the benchmark for the four corner sensors 160, 162, 164, 166. Each individual pressure sensor may be considered as having its own benchmark, with an overall system benchmark being met when each individual benchmark is met.

Referring to step 265 of FIG. 4, if the benchmark is not met, then the individual fastener(s) are adjusted to change their applied force. This continues until setup quality is met, or in other words the benchmark is met. In step 270, the semiconductor package, containing one or more CPUs or GPUs, is then operated. The resulting structure is shown in FIG. 1.

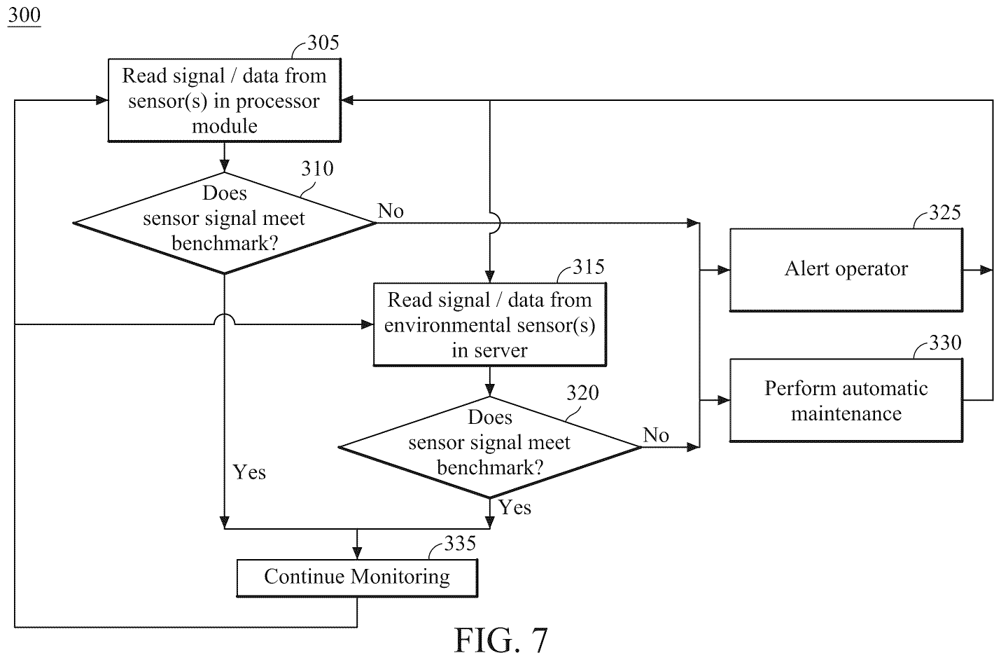

FIG. 7 is a flow chart illustrating a method 300 for maintaining a processor module in a server, in accordance with some embodiments. Some steps of the method are also illustrated in FIG. 5 and FIG. 6. The method steps are discussed below in terms of a single sensor in a single processor module during its operational lifetime after installation, and should be construed as also applying to multiple sensors in a given processor module, and to multiple sensors across multiple processor modules. Generally, the monitoring system provides alerts when maintenance is needed. This may occur, for example, due to loosening of the fasteners due to aging of the springs, pump-out of thermal interface material, or die crack. Different conditions can be detected by different sensors.

In step 305 of FIG. 7, the signal from a sensor in a processor module is read. In step 310, the signal from the sensor is compared to at least one benchmark to determine whether maintenance is needed. The comparison(s) may be performed, for example, by the monitoring system 176.

The benchmark(s) may vary depending, for example, on the location of the sensor and the type of sensor. For example, for a pressure sensor, the benchmark may be whether the pressure is at a target pressure value or within a target pressure range. For a displacement sensor, the benchmark may be whether there has been an unacceptably high change in length or an unacceptably high change in position. For a temperature, the benchmark may be whether the measured temperature is within a set temperature range. In embodiments where multiple sensors of the same type are present, the benchmark could be related to differences between the sensor data at different locations. For example, the benchmark could be whether the temperature difference between a sensor at a corner of the package and a sensor at the center of the package is within a set temperature range. As another example, the benchmark could be whether the displacement between a sensor at a corner of the package and a sensor at the center of the package is within a set range (which could indicate pump-out). The benchmark could also be a change in value measured by the same sensor within a certain time period. For example, a sudden change in the value measured by a particular strain sensor might be indicative of die crack.

The benchmark against which the sensor signal is compared does not need to be static, and could potentially change over time. For example, a temperature benchmark could be whether the measured temperature for a given processor module is within one, two, or three standard deviations of the average measured temperature for all processor modules in a given server. This would identify whether the processor module is an outlier and should be checked by maintenance personnel.

If maintenance is needed, the monitoring system can perform at least two different actions. First, in step 325 of FIG. 7, the monitoring system can alert an operator that maintenance is needed. This could be done, for example, by activating a visual alarm and/or an audio alarm, generating an error message, or sending a text message, etc. The output from the monitoring system could provide information on which processor module may need maintenance, which sensor was triggered, what benchmark was violated, etc. Second, in step 330 of FIG. 7, the monitoring system may automatically perform maintenance. For example, if the monitoring system indicates maintenance is needed due to a heat sink spring-loaded screw becoming too loose, the monitoring system could direct a robotic screwdriver to tighten the loose screw until the sensor signal falls within the benchmark. As another example, if the temperature of a processor module is too high, the monitoring system could cut off the power to that processor module or increase the rate of coolant flow to that processor module.

Similarly, as indicated in step 315 of FIG. 7, the signal from a first environmental sensor 174 in the server can also be read. In step 320, the signal from the first environmental sensor is compared to at least one benchmark to determine whether maintenance is needed. In steps 325 and 330, if maintenance is needed, the monitoring system can alert an operator or perform automatic maintenance. It is contemplated that these steps would be performed at the server level rather than at the level of each individual processor module, although this is not required. For example, if the temperature measured by the environmental sensor is much higher than the average temperature of the processor modules in the server, this could indicate a problem with the cooling system for the server. As another example, a measured humidity value that is much higher than the humidity of the ambient environment might indicate a leak in a liquid cooling system being used within the server. In step 335, if maintenance is not needed and all benchmarks are met, then monitoring continues.

The monitoring system can also use the data derived from the sensors of multiple servers to identify potential maintenance issues. For example, if the average temperature of the processor modules in server A is significantly higher than the average temperature of the processor modules in server B, this might indicate a maintenance issue in server A. Similar benchmarking may occur at the data center maintenance center 178 of FIG. 3, where data is compared between different servers and different data centers to identify potential maintenance issues and identify operating improvements that could be made.

The overall goal is to improve the performance of the data center. This could be measured, for example, in terms of how much power is needed to obtain the same cooling efficiency, or the chip temperature for the same power input. As a result, the servers and data centers that use processor modules with sensors to measure one or more parameters (especially pressure and/or temperature) have improved thermal performance, improved reliability, and reduced defects.

Some embodiments of the present disclosure thus relate to methods for applying a heat sink to a semiconductor package. A thermal interface material is applied to the semiconductor package to form a thermal interface layer. At least one pressure sensor is aligned between the semiconductor package and a heat sink. The heat sink is secured over the semiconductor package using a fastener system. A signal is read from the at least one pressure sensor. The signal from the at least one pressure sensor is compared to a benchmark to determine whether setup quality is met. The fastener system is adjusted until the setup quality is met.

Other embodiments disclosed herein relate to methods for maintaining a processor module in a server. A signal is read from at least one sensor in the processor module. The signal from the at least one sensor is compared to a benchmark to determine whether maintenance is needed. When maintenance is needed, either (i) an operator is alerted, or (ii) the maintenance is automatically performed.

Also described in various embodiments herein are data center systems, comprising at least one server and a monitoring system. Each server comprises a plurality of processor modules. Each processor module comprises: a semiconductor package mounted on a motherboard; a heat sink over the semiconductor package; a thermal interface material between the semiconductor package and the heat sink; and at least one sensor located between the semiconductor package and the heat sink. The monitoring system is configured to process data received from each sensor in the plurality of processor modules and alert an operator when maintenance is needed for a processor module.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for applying a heat sink to a semiconductor package, comprising:
applying a thermal interface material to the semiconductor package;
aligning at least one pressure sensor between the semiconductor package and a heat sink;
securing the heat sink over the semiconductor package using a fastener system;
reading a signal from the at least one pressure sensor;
comparing the signal from the at least one pressure sensor to a benchmark to determine whether setup quality is met; and
adjusting the fastener system until the setup quality is met.

2. The method of claim 1, wherein the at least one pressure sensor is configured to send the data wirelessly.

3. The method of claim 1, wherein the at least one pressure sensor comprises a plurality of pressure sensors spaced about a perimeter of the semiconductor package.

4. The method of claim 1, wherein the at least one pressure sensor comprises a pressure sensor over a center of the semiconductor package.

5. The method of claim 1, wherein the at least one pressure sensor is embedded in the heat sink or in a lid of the semiconductor package.

6. The method of claim 1, wherein the at least one pressure sensor is a pneumatic pressure sensor, a hydraulic pressure sensor, a strain gauge, or a capacitive pressure sensor.

7. A method for maintaining a processor module in a server, comprising:
reading a signal from at least one sensor in the processor module;
comparing the signal from the at least one sensor to a benchmark to determine whether maintenance is needed; and
either (i) alerting an operator when maintenance is needed, or (ii) automatically performing the maintenance.

8. The method of claim 7, further comprising
reading a signal from a first environmental sensor located within the server, the first environmental sensor configured to measure temperature, humidity, or moisture;
comparing the signal from the first environmental sensor to a benchmark to determine whether maintenance is needed; and
either (i) alerting an operator when maintenance is needed, or (ii) automatically performing the maintenance.

9. The method of claim 7, wherein the at least one sensor is configured to measure pressure, force, displacement, stress, strain, temperature, and combinations thereof.

10. The method of claim 7, wherein the at least one sensor comprises a pressure sensor and a temperature sensor.

11. A data center system, comprising:
at least one server comprising a plurality of processor modules, each module comprising:
a semiconductor package mounted on a motherboard;
a heat sink over the semiconductor package;
a thermal interface material between the semiconductor package and the heat sink; and
at least one sensor located between the semiconductor package and the heat sink; and
a monitoring system configured to process data received from each sensor in the plurality of processor modules and alert an operator when maintenance is needed for a processor module.

12. The system of claim 11, wherein the at least one sensor in each processor module comprises sensors configured to measure pressure, force, displacement, stress, strain, temperature, and combinations thereof.

13. The system of claim 11, wherein the at least one sensor in each processor module comprises a pressure sensor and a temperature sensor.

14. The system of claim 11, wherein the at least one sensor in each processor module is configured to send the data wirelessly.

15. The system of claim 11, wherein the at least one sensor in each processor module comprises a plurality of pressure sensors spaced about a perimeter of the semiconductor package.

16. The system of claim 11, wherein the at least one sensor in each processor module is embedded in the heat sink or in a lid of the semiconductor package.

17. The system of claim 11, wherein the at least one sensor in each processor module is a pneumatic pressure sensor, a hydraulic pressure sensor, a strain gauge, or a capacitive pressure sensor.

18. The system of claim 11, further comprising a first environmental sensor located within the at least one server, the first environmental sensor configured to measure temperature, humidity, or moisture.

19. The system of claim 11, wherein the at least one server is a plurality of servers that each send data to the monitoring system.

20. The system of claim 11, wherein the system is also configured to send the data to a data center maintenance center.
